(19) United States
(12) Patent Application Publication
(10) Pub. No.: US 2024/0324285 A1
(43) Pub. Date: Sep. 26, 2024

(54) DISPLAY APPARATUS AND METHOD OF MANUFACTURING THE SAME

(71) Applicant: Samsung Display Co., Ltd., Yongin-Si (KR)

(72) Inventors: Moosoon Ko, Yongin-si (KR); Kohei Ebisuno, Yongin-si (KR); Sanghoon Oh, Yongin-si (KR); Jaesoo Jung, Yongin-si (KR)

(21) Appl. No.: 18/426,365

(22) Filed: Jan. 30, 2024

(30) Foreign Application Priority Data
Mar. 24, 2023 (KR) 10-2023-0039049
Mar. 29, 2023 (KR) 10-2023-0041536

(51) Int. Cl. H10K 59/121; H10K 59/12

(52) U.S. Cl. CPC H10K 59/1213; H10K 59/1201

(57) ABSTRACT

A display apparatus and a manufacturing method may avoid electrical shorting caused by protrusion structures that result from a difference in etch rates. The display apparatus includes a substrate, a semiconductor layer on the substrate, a first metal layer arranged on the semiconductor layer, insulated from the semiconductor layer, and including a first metal layer having a first etch rate under a predetermined condition, and a second metal layer arranged on the first metal layer, contacting an upper surface of the first metal layer, including a second metal material having a second etch rate under the predetermined condition, the second etch rate being less than the first etch rate, and arranged in the upper surface of the first metal layer when viewed in a direction perpendicular to the substrate.

### CROSS-REFERENCE TO RELATED APPLICATIONS

This application is based on and claims priority under 35 U.S.C. § 119 to Korean Patent Applications Nos. 10-2023-0039049 and 10-2023-0041536, respectively filed on Mar. 24, 2023 and Mar. 29, 2023, in the Korean Intellectual Property Office, the disclosures of which are incorporated by reference herein in their entirety.

### BACKGROUND

### 1. Field

One or more embodiments relate to a display apparatus and a method of manufacturing the same, and more particularly, to a display apparatus and a manufacturing method for preventing shorts caused by protrusion structures that may otherwise result from an etch rate difference during manufacturing of the display apparatus.

### 2. Description of the Related Art

A display apparatus may receive information about an image and display the image. A display apparatus may be a display in a small-sized product such as a cellular phone, etc. or a display in a large-sized product such as a television, etc.

The display apparatus may include pixels, which receive an electrical signal and then emit light, to display an image. Each pixel may include a light-emitting element. For example, an organic light-emitting display apparatus may include organic light-emitting diodes as the light-emitting elements. Generally, an organic light-emitting display apparatus includes a thin-film transistor and an organic light-emitting diode formed on a substrate and operates the organic light-emitting diode to directly emit light. The display apparatus may further include a storage capacitor, and research into storage capacitor structures is continually being conducted.

### SUMMARY

One or more embodiments described herein include a display apparatus that avoids shorts that might otherwise be result when an etch rate difference during manufacturing the display apparatus creates a protrusion structure. However, this objective is an example and does not limit the scope of the disclosure.

Additional aspects will be set forth in part in the description which follows and, in part, will be apparent from the description, or may be learned by practice of the presented embodiments of the disclosure.

According to one or more embodiments, a display apparatus includes a substrate, a semiconductor layer arranged on the substrate, a first metal layer arranged on the semiconductor layer, insulated from the semiconductor layer, and including a first metal material having a first etch rate under a predetermined condition, and a second metal layer arranged on the first metal layer, contacting an upper surface of the first metal layer, and arranged within boundaries of the upper surface of the first metal layer when viewed in a direction perpendicular to the substrate. The second metal layer includes a second metal material having a second etch rate under the predetermined condition, the second etch rate being less than the first etch rate.

The first metal material may include aluminum (AI), and the second metal material may include titanium (Ti).

The second metal layer may include a first sub-layer contacting the upper surface of the first metal layer and including a nitride of the second metal material and a second sub-layer contacting an upper surface of the first sub-layer and including the second metal material.

When viewed in the direction perpendicular to the substrate, the second sub-layer may be arranged within boundaries of the upper surface of the first sub-layer.

When viewed in the direction perpendicular to the substrate, an edge of a contact surface at which a lower surface of the first sub-layer and the upper surface of the first metal layer contact each other may be spaced apart from an edge of the upper surface of the first metal layer.

A side surface of the second metal layer may have a stair-shaped step difference with respect to the upper surface of the first metal layer.

The first metal layer may include a first side surface extending at a first acute angle relative to an upper surface of the substrate, and the second metal layer may include a second side surface extending at a second acute angle relative to the upper surface of the substrate, the second acute angle being less than the first acute angle.

According to one or more embodiments, a method of manufacturing a display apparatus includes forming a semiconductor layer on a substrate, forming, on the semiconductor layer, a first metal layer including a first metal material having a first etch rate under a predetermined condition, forming, on the first metal layer, a second metal layer including a second metal material having a second etch rate under the predetermined condition, etching the second metal layer and a portion of the first metal layer, and forming an undercut structure at a side surface of the first metal layer. The undercut structure includes a protrusion portion of the second metal layer that extends beyond the side surface of the first metal layer, and the method of manufacturing further includes etching the protrusion portion of the second metal layer.

The forming of the second metal layer may include forming, on the first metal layer, a first sub-layer including a nitride of the second metal material and forming, on the first sub-layer, a second sub-layer including the second metal material.

The first metal material may include aluminum (AI), and the second metal material may include titanium (Ti).

The etching of the second metal layer and the portion of the first metal layer may include etching the second metal layer and the portion of the first metal layer by using a first etching gas including chlorine (Cl₂) gas and boron trichloride (BCl₃) gas.

In the first etching gas, a ratio between a flow rate of the Cl₂ gas and a flow rate of the BCl₃ gas may be in a range from 10:1 to 1:2.

The forming of the undercut structure at the side surface of the first metal layer may include etching the first metal layer by using a second etching gas including Cl₂ gas, BCl₃ gas, and nitrogen gas (N₂ gas).

In the second etching gas, a flow rate of the Cl₂ gas, a flow rate of the BCl₃ gas, and a flow rate of the N₂ gas may be in relative proportions in a range 1:0.33:0.15 to 1:5:0.15 or 1:3:0.05 to 1:3:3.

The etching of the protrusion portion of the second metal layer may include etching the protrusion portion of the second metal layer by using a third etching gas including tetrafluoromethane (CF₄) gas and argon (Ar) gas.

In the third etching gas, a ratio between a flow rate of the CF₄ gas and a flow rate of the Ar gas may be in a range from 1:5 to 1:1.

The protrusion portion may include a lower surface of the second metal layer, the lower surface protruding from an upper surface of the first metal layer in a direction parallel to the substrate.

The first metal layer may include a first side surface extending at a first acute angle relative to an upper surface of the substrate, and the second metal layer may include a second side surface extending at a second acute angle relative to the upper surface of the substrate, the second acute angle being less than the first acute angle.

The etching of the protrusion portion of the second metal layer may include etching the protrusion portion of the second metal layer such that a side surface of the second metal layer has a stair-shaped step difference with respect to an upper surface of the first metal layer.

The etching of the protrusion portion of the second metal layer may include etching the protrusion portion of the second metal layer such that, when viewed in a direction perpendicular to the substrate, an edge of a contact surface at which a lower surface of the second metal layer and an upper surface of the first metal layer contact each other is spaced apart from an edge of the upper surface of the first metal layer.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic plan view of a display panel of a display apparatus according to an embodiment.

FIG. 2 is an equivalent circuit diagram of a pixel included in the display panel of FIG. 1.

FIG. 3 is a schematic cross-sectional view of a portion of the display panel of FIG. 1.

FIG. 4 is a schematic cross-sectional view of a region A of FIG. 3.

FIGS. 5, 6, 7, 8, and 9 are schematic cross-sectional views of the region A of FIG. 3 for sequentially describing a method of manufacturing a display apparatus according to another embodiment.

FIG. 10 is a cross-sectional view schematically illustrating a display apparatus by focusing on a first metal layer and a second metal layer of the display apparatus according to a comparative embodiment.

FIG. 11 is a cross-sectional view schematically illustrating a display apparatus by focusing on a first metal layer and a second metal layer of the display apparatus according to an embodiment.

### DETAILED DESCRIPTION

Reference will now be made in detail to embodiments, examples of which are illustrated in the accompanying drawings, wherein like reference numerals refer to like elements. In this regard, the embodiments in accordance with the present disclosure may have different forms and should not be construed as being limited to the descriptions set forth herein. Accordingly, the embodiments are merely described below, by referring to the figures, to explain aspects of the present description.

While the disclosure is capable of various modifications and alternative forms, embodiments thereof are shown by way of example in the drawings and will herein be described in detail. Effects and characteristics of the disclosure and realizing methods thereof will become apparent by referring to the drawings and embodiments described in detail below. However, the disclosure is not limited to the embodiments disclosed hereinafter and may be realized in various forms.

Hereinafter, embodiments of the disclosure will be described in detail by referring to the accompanying drawings. In descriptions with reference to the drawings, the same reference numerals are given to elements that are the same or substantially the same and descriptions will not be repeated.

In embodiments to be described hereinafter, when elements, such as a layer, a film, an area, a plate, etc. are referred to as being “on” another element, the reference may indicate not only a case where the element is “directly on” the other element, but also a case where yet another element is between the element and the other element. Also, for convenience of explanation, elements in the drawings may have exaggerated or reduced sizes. For example, sizes and thicknesses of the elements in the drawings are indicated for convenience of explanation, and thus, the disclosure is not necessarily limited to the illustrations of the drawings. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

In the embodiments hereinafter, the x-axis, the y-axis and the z-axis are not limited to three axes of a rectangular coordinate system and may be interpreted in a broader sense. For example, the x-axis, the y-axis, and the z-axis may be perpendicular to one another, or may represent different directions that are not perpendicular to one another.

Hereinafter, a display apparatus according to an embodiment is described in detail based on the above descriptions.

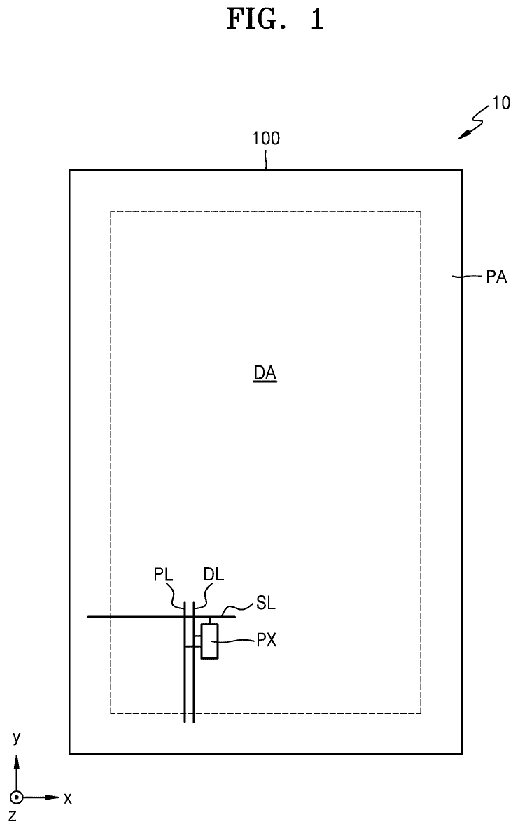

FIG. 1 is a schematic plan view of a display panel 10 of a display apparatus according to an embodiment. The display apparatus may be of any type of display apparatus that includes the display panel 10. For example, the display apparatus may be a smartphone, a tablet computer, a laptop, a television, an advertising board, or the like. The display apparatus according to an embodiment may include thin-film transistors, a capacitor, etc., wherein the thin-film transistors, the capacitor, etc. may be realized by conductive layers and insulating layers.

The display panel 10 may include a display area DA and a peripheral area PA outside the display area DA. FIG. 1 illustrates that the display area DA has a rectangular shape. However, the disclosure is not limited thereto. The display area DA may have various shapes, such as a circular shape, an oval shape, a polygonal shape, a shape of a predetermined figure, etc.

The display area DA is an area in which an image is displayed, and a plurality of pixels PX may be arranged in the display area DA. Each pixel PX may include a display device, such as an organic light-emitting diode. Each pixel PX may emit, for example, red, green, or blue light. The pixel PX may be connected to a pixel circuit including a thin-film transistor, a storage capacitor, etc. The pixel circuit may be connected to a scan line SL configured to transmit a scan signal, a data line DL crossing the scan line SL and configured to transmit a data signal, a driving voltage line PL configured to supply a driving voltage, etc. The scan line SL may extend in an x direction (hereinafter, a second direction), and the data line DL and the driving voltage line PL may extend in a y direction (hereinafter, a first direction).

Each pixel PX may emit light having a brightness corresponding to an electrical signal from the pixel circuit electrically connected to the pixel PX. The display area DA may display a predetermined image through the light emitted from all the pixels PX. For reference, each pixel PX may be defined as an emission area in which any one of red, green, and blue light is emitted as described above.

The peripheral area PA is an area in which the pixel PX is not arranged and may be an area in which an image is not displayed. A power supply line, etc. configured to drive the pixel PX may be arranged to extend into the peripheral area PA. Also, a plurality of pads may be arranged in the peripheral area PA, and a printed circuit board including a driving circuit portion or an integrated circuit device, such as a driver integrated circuit (IC), may be electrically connected to the plurality of pads.

For reference, the display panel 10 may include a substrate 100, and thus, it may be described that the substrate 100 may include the display area DA and the peripheral area PA. Detailed aspects with respect to the substrate 100 will be described below.

Also, a plurality of transistors may be arranged in the display area DA. With respect to the plurality of transistors, according to types (N types or P types) and/or operation conditions of the transistors, first terminals of the transistors may be source electrodes or drain electrodes, and second terminals may be electrodes different from the electrodes of the first terminals. For example, when the first terminal is a source electrode, the second terminal may be a drain electrode.

The plurality of transistors may include a driving transistor, a data write transistor, a compensation transistor, an initialization transistor, an emission control transistor, etc. The driving transistor may be connected between the driving voltage line PL and an organic light-emitting diode OLED, and the data write transistor may be connected to the data line DL and the driving transistor and may be configured to perform a switching operation of transmitting, to the driving transistor, a data signal transmitted through the data line DL.

The compensation transistor may be turned on according to a scan signal transmitted through the scan line SL and configured to connect the driving transistor with the organic light-emitting diode OLED to compensate for a threshold voltage of the driving transistor.

The initial transistor may be turned on according to a scan signal transmitted through the scan line SL and configured to transmit an initialization voltage to a gate electrode of the driving transistor to initialize the gate electrode of the driving transistor. The scan line connected to the initialization transistor may be a different scan line from the scan line connected to the compensation transistor.

The emission control transistor may be turned on according to an emission control signal transmitted through an emission control line, and as a result, a driving current may flow through the organic light-emitting diode OLED.

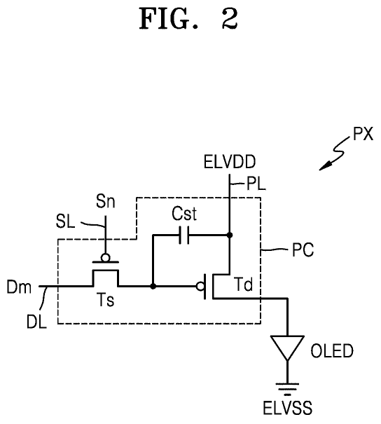

The organic light-emitting diode OLED may include a pixel electrode (an anode) and an opposite electrode (a cathode), and the opposite electrode may receive a power voltage, e.g., the second power voltage ELVSS in FIG. 2. The organic light-emitting diode OLED may emit light by receiving a driving current from the driving transistor to display an image.

An organic light-emitting display apparatus is described as an example of the display apparatus according to an embodiment. However, the display apparatus according to an embodiment is not limited thereto. The display apparatus according to another embodiment may include an inorganic light-emitting display apparatus, an inorganic electroluminescent (EL) display apparatus, or a quantum dot light-emitting display apparatus. That is, an emission layer of a display device included in the display apparatus may include an organic material or an inorganic material. Also, the display apparatus may include the emission layer and quantum dots located on a path of the light emitted from the emission layer.

FIG. 2 is an equivalent circuit diagram of a pixel PX suitable for the display panel 10 of FIG. 1. As illustrated in FIG. 2, each pixel PX may include a pixel circuit PC connected to a scan line SL and a data line DL and include an organic light-emitting diode OLED connected to the pixel circuit PC.

The pixel circuit PC may include a driving thin-film transistor Td, a switching thin-film transistor Ts, and a storage capacitor Cst. The switching thin-film transistor Ts may be connected to the scan line SL and the data line DL and may be configured to transmit a data signal Dm provided through the data line DL, to the driving thin-film transistor Td, in response to a scan signal Sn provided to the switching thin film transistor Ts through the scan line SL.

The storage capacitor Cst may be connected to the switching thin-film transistor Ts and a driving voltage line PL and may be configured to store a voltage corresponding to a difference between a voltage received from the switching thin-film transistor Ts and a first power voltage ELVDD supplied to the driving voltage line PL.

A second power voltage ELVSS may be a driving voltage having a relatively lower level than the first power voltage ELVDD. A level of a driving voltage supplied to each pixel PX may be a difference between a level of the first power voltage ELVDD and a level of the second power voltage EVLSS.

The driving thin-film transistor Td may be connected to the driving voltage line PL and the storage capacitor Cst and may be configured to control a driving current flowing from the driving voltage line PL through the organic light-emitting diode OLED according to a value of a voltage stored in the storage capacitor Cst. The organic light-emitting diode OLED may emit light having a certain brightness according to the driving current.

The pixel circuit PC as illustrated in FIG. 2 may include two thin-film transistors and one storage capacitor. However, the disclosure is not limited thereto. For example, the pixel circuit PC may include two or more storage capacitors.

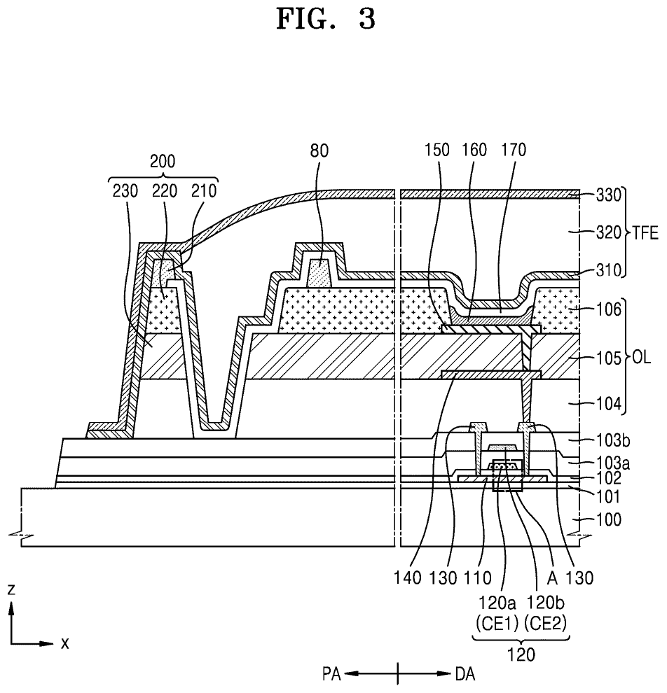

FIG. 3 is a schematic cross-sectional view of a portion of the display panel 10 of FIG. 1. As described above, the display panel includes the substrate 100, which may include areas corresponding to the display area DA and the peripheral area PA outside the display area DA. The substrate 100 may include various materials having flexible or bendable properties. For example, the substrate 100 may include glass, metal, or polymer resins. In an embodiment, the substrate 100 may include polymer resins, such as polyethersulphone, polyacrylate, polyetherimide, polyethylene naphthalate, polyethylene terephthalate, polyphenylene sulfide, polyarylate, polyimide, polycarbonate, or cellulose acetate propionate. However, various modifications may be possible. For example, the substrate 100 may have a multi-layered structure including: two layers each including the polymer resins described above; and a barrier layer between the two layers, the barrier layer including an inorganic material (such as silicon oxide, silicon nitride, silicon oxynitride, or the like).

A buffer layer 101 may be arranged on the substrate 100. The buffer layer 101 may prevent diffusion of impurity ions, prevent the penetration of water or external materials, and function as a barrier layer for planarizing a surface and/or a blocking layer. The buffer layer 101 may include silicon oxide, silicon nitride, or silicon oxynitride. Also, the buffer layer 101 may control a heat provision speed during a crystallization process for forming a semiconductor layer 110, so that the semiconductor layer 110 may be uniformly crystallized.

The semiconductor layer 110 may be arranged on the buffer layer 101. The semiconductor layer 110 may include polysilicon and may include a channel area not doped with impurities and a source area and a drain area at both sides of the channel area that are doped with impurities. Here, the impurities may vary according to types of thin-film transistors and may include N-type impurities or P-type impurities.

A gate insulating layer 102 may be arranged on the semiconductor layer 110. The gate insulating layer 102 may be configured to obtain an insulating property between the semiconductor layer 110 and a gate layer 120. The gate insulating layer 102 may include an inorganic material, such as silicon oxide, silicon nitride, and/or silicon oxynitride, and may be arranged between the semiconductor layer 110 and the gate layer 120. Also, the gate insulating layer 102 may extend across the entire surface of the substrate 100 and may have through-holes in predetermined portions. The gate insulating layer 102 including an inorganic material may be formed by chemical vapor deposition (CVD) or atomic layer deposition (ALD). This aspect may be the same for embodiments described below and for modified embodiments.

The gate layer 120 may include a first gate layer 120a and a second gate layer 120b. The first gate layer 120a may be arranged on the gate insulating layer 102. The first gate layer 120a may particularly be arranged above the semiconductor layer 110 to overlap the semiconductor layer 110 and may include at least one metal from among Mo, Al, Pt, Pd, Ag, Mg, Au, Ni, Nd, Ir, Cr, Li, Ca, Ti, W, and Cu.

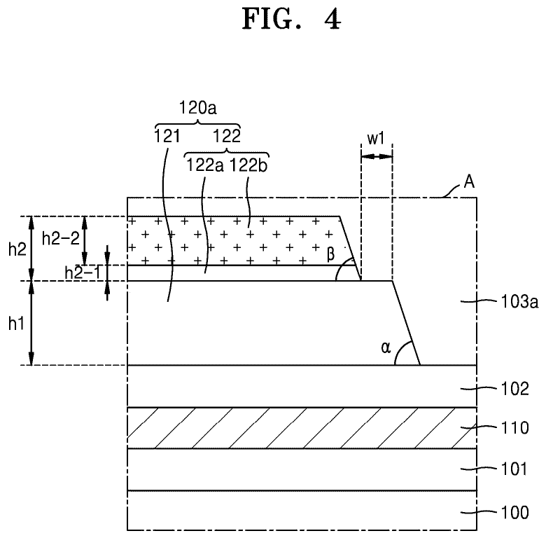

The first gate layer 120a may include a first metal layer 121 including a first metal material and a second metal layer 122 including a second metal material as described below with reference to FIG. 4. The second metal layer 122 may be arranged on the first metal layer 121, and the first metal layer 121 may be arranged on the gate insulating layer 102. Detailed aspects of the first metal layer 121 and the second metal layer 122 are described below.

A first interlayer insulating layer 103a may be arranged on the first gate layer 120a. The first interlayer insulating layer 103a may cover the first gate layer 120a. The first interlayer insulating layer 103a may include an inorganic material. For example, the first interlayer insulating layer 103a as shown in FIG. 3 may include a metal oxide or a metal nitride. Specifically, the inorganic material may include SiO₂, SiNₓ, SiON, Al₂O₃, TiO₂, TA₂O₅, HfO₂, or ZnO₂. According to some embodiments, the first interlayer insulating layer 103a may have a multilayer or dual structure of SiOₓ/SiN_{y} or SiNₓ/SiO_{y}.

A second gate layer 120b may be arranged on the first interlayer insulating layer 103a. The second gate layer 120b may be arranged above the first gate layer 120a to overlap the first gate layer 120a and may include at least one metal from among Mo, Al, Pt, Pd, Ag, Mg, Au, Ni, Nd, Ir, Cr, Li, Ca, Ti, W, and Cu.

The second gate layer 120b, the first gate layer 120a, and a portion of the first interlayer insulating layer 103a may form the storage capacitor Cst described above with reference to FIG. 2. The first gate layer 120a may include a first electrode portion CE1 of the storage capacitor Cst, and the second gate layer 120b may include a second electrode portion CE2 of the storage capacitor Cst.

When viewed in a direction perpendicular to the substrate 100, an area of the second gate layer 120b may be greater than an area of the first gate layer 120a. Alternatively, when viewed in the direction perpendicular to the substrate 100, the second gate layer 120b may cover the first gate layer 120a.

A second interlayer insulating layer 103b may be arranged on the second gate layer 120b. The second interlayer insulating layer 103b may cover the second gate layer 120b. The second interlayer insulating layer 103b may include an inorganic material. For example, the second interlayer insulating layer 103b may include a metal oxide or a metal nitride. Specifically, the inorganic material in the second interlayer insulating layer 103b may include SiO₂, SiNₓ, SiON, Al₂O₃, TiO₂, TA₂O₅, HfO₂, or ZnO₂. According to some embodiments, the second interlayer insulating layer 103b may have a multilayer or dual structure of SiOₓ/SiN_{y} or SiNₓ/SiO_{y}.

A first conductive layer 130 may be arranged above the second interlayer insulating layer 103b. Portions of the first conductive layer 130 may serve as electrodes respectively connected to the source area and the drain area of the semiconductor layer through respective through-holes extending through the second interlayer insulating layer 103b and the gate insulating layer 102. The first conductive layer 130 may include one or more metals selected from among Al, Pt, Pd, Ag, Mg, Au, Ni, Nd, Ir, Cr, Li, Ca, Mo, Ti, W, and Cu. For example, the first conductive layer 130 may include a Ti layer, an Al layer, and/or a Cu layer.

A first organic insulating layer 104 may be arranged on the first conductive layer 130. The first organic insulating layer 104 may cover an upper portion of the first conductive layer 130 and may have an approximately flat upper surface to serve as a planarization layer. The first organic insulating layer 104 may include, for example, an organic material, such as acryl, benzocyclobutene (BCB), or hexamethyldisiloxane (HMDSO). The first organic insulating layer 104 may include a single layer or multiple layers and may be modified in various ways.

A second conductive layer 140 may be arranged above the first organic insulating layer 104. A portion of the second conductive layer 140 may serve as an electrode connected to the source area or the drain area of the semiconductor layer 110 through a through-hole that extends through the first organic insulating layer 104 to the first conductive layer 130. The second conductive layer 140 may include one or more metals selected from among Al, Pt, Pd, Ag, Mg, Au, Ni, Nd, Ir, Cr, Li, Ca, Mo, Ti, W, and Cu. For example, the second conductive layer 140 may include a Ti layer, an Al layer, and/or a Cu layer.

A second organic insulating layer 105 may be arranged on the second conductive layer 140. The second organic insulating layer 105 may cover an upper portion of the second conductive layer 140 and may have an approximately flat upper surface to serve as a planarization layer. The second organic insulating layer 105 may include, for example, an organic material, such as acryl, BCB, or HMDSO. The second organic insulating layer 105 may include a single layer or multiple layers and may be modified in various ways.

A pixel electrode 150 may be arranged on the second organic insulating layer 105. The pixel electrode 150 may be connected to the second conductive layer 140 through a contact hole formed in the organic insulating layer 105. Also, although not illustrated in FIG. 3, an additional conductive layer (not shown) and an additional insulating layer (not shown) may be between the second conductive layer 105 and the pixel electrode 150, and various other interconnection structures may be implemented. Here, the additional conductive layer may include the same material and the same layer structure as the first or second conductive layer described above. The additional insulating layer may include the same material and the same layer structure as the first or second organic insulating layer described above.

A display device may be arranged on the pixel electrode 150. As the display device, an organic light-emitting diode OLED may be used. That is, the organic light-emitting diode OLED may be, for example, arranged on the pixel electrode 150. The pixel electrode 150 may include a transmissive conductive layer including transmissive conductive oxide, such as ITO, In₂O₃, or IZO, and a reflection layer including metal, such as Al or Ag. For example, the pixel electrode 150 may have a triple-layered structure of ITO/Ag/ITO.

A pixel-defining layer 106 may be arranged on the second organic insulating layer 105 to cover an edge of the pixel electrode 150. That is, the pixel-defining layer 106 may cover the edge of the pixel electrode 150. The pixel-defining layer 106 may have an opening portion corresponding to the pixel PX, and the opening portion may be formed to expose at least a central portion of the pixel electrode 150. The pixel-defining layer 106 may include, for example, an organic material, such as polyimide or HMDSO. Also, a spacer 80 may be arranged on the pixel-defining layer 106.

FIG. 3 illustrates that the spacer 80 may be arranged in the peripheral area PA, but the spacer 80 may instead be arranged in the display area DA. The spacer 80 may prevent damage to the organic light-emitting diode OLED, which may be caused by sagging of a mask during a manufacturing process using the mask. The spacer 80 may include an organic insulating material and may include a single layer or layers.

An intermediate layer 160 and an opposite electrode 170 may be arranged in the opening portion of the pixel-defining layer 106. The intermediate layer 160 may include a low-molecular-weight material or a high-molecular-weight material, and when the intermediate layer 160 includes a low-molecular-weight material, the intermediate layer 160 may include a hole injection layer, a hole transport layer, an emission layer, an electron transport layer, and/or an electron injection layer. When the intermediate layer 160 includes a high-molecular-weight material, the intermediate layer 160 may generally have a structure including a hole transport layer and an emission layer.

The opposite electrode 170 may include a transmissive conductive layer including transmissive conductive oxide, such as ITO, In₂O₃, or IZO. The pixel electrode 150 may be used as an anode, and the opposite electrode 170 may be used as a cathode of a light-emitting diode. However, polarities of the electrodes may be the opposite.

A structure of the intermediate layer 160 is not limited to the structure described above, and the intermediate layer 160 may have various structures. For example, at least one of layers included in the intermediate layer 160 may be integrally formed like the opposite electrode 170. According to another embodiment, the intermediate layer 160 may include layers respectively patterned to correspond to a plurality of pixel electrodes 150.

The opposite electrode 170 may be arranged above the display area DA and may extend across or throughout the display area DA. That is, the opposite electrode 170 may be integrally formed to cover a plurality of pixels. The opposite electrode 170 may be electrically connected to a common power supply line (not shown) arranged in the peripheral area PA. According to an embodiment, the opposite electrode 170 may extend to a partition wall 200. A thin-film encapsulation layer TFE may entirely cover the display area DA and extend to the peripheral area PA to cover at least a portion of the peripheral area PA.

The thin-film encapsulation layer TFE may extend to an outer portion of the common power supply line. The thin-film encapsulation layer TFE may include a first inorganic encapsulation layer 310, a second inorganic encapsulation layer 330, and an organic encapsulation layer 320 arranged therebetween. The first and second inorganic encapsulation layers 310 and 330 may include one or more inorganic materials from among Al₂O₃, TiO, TA₂O₅, HfO₂, ZnO, SiOₓ, SiNₓ, and SiON.

The first and second inorganic encapsulation layers 310 and 330 may include a single layer or multiple layers including the materials described above. The first and the second inorganic encapsulation layers 310 and 330 may include the same material as each other or different materials from each other. Thicknesses of the first and second inorganic encapsulation layers 310 and 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first and second inorganic encapsulation layer 310 and 330 may be the same as each other.

The organic encapsulation layer 320 may include a monomer-based material or a polymer-based material. The polymer-based material may include acryl-based resins, epoxy-based resins, polyimide, polyethylene, etc. According to an embodiment, the organic encapsulation layer 320 may include acrylate.

The partition wall 200 may be arranged in the peripheral area PA of the substrate 100. According to an embodiment, the partition wall 200 may include a portion of the first organic insulating layer 104, a portion 230 of the second organic insulating layer 105, a portion 220 of the pixel-defining layer 106, and a portion 210 of the spacer 80, but is not necessarily limited thereto.

In certain cases, the partition wall 200 may include only the portion 230 of the second organic insulating layer 105 or only the portion 220 of the pixel-defining layer 106. The partition wall 200 may be arranged to surround the display area DA and may prevent overflowing of the organic encapsulation layer 320 of the thin-film encapsulation layer TFE to the outside of the substrate 100. Thus, the organic encapsulation layer 320 may contact an inner surface of the partition wall 200 toward the display area DA. Here, that the organic encapsulation layer 320 contacts the inner surface of the partition wall 200 may be understood as that the first inorganic encapsulation layer 310 may be arranged between the organic encapsulation layer 320 and the partition wall 200, and the organic encapsulation layer 320 may contact the first inorganic encapsulation layer 310 on the partition wall 200.

The first inorganic encapsulation layer 310 and the second inorganic encapsulation layer 330 may be arranged on the partition wall 200 and may extend to an edge of the substrate 100. However, in certain cases, the partition wall 200 may include multiple barriers or walls having the same or similar structure as described for the partition wall 100.

FIG. 4 is a schematic cross-sectional view of a region A of FIG. 3. For reference, the region A of FIG. 3 may indicate a portion of a display apparatus manufactured by a method of manufacturing a display apparatus according to another embodiment, which is described below.

As illustrated in FIG. 4, the display apparatus according to an embodiment may include the substrate 100, the semiconductor layer 110, and the first gate layer 120a including a first metal layer 121, and a second metal layer 122.

The first metal layer 121 may be arranged on the gate insulating layer 102 as described above and for convenience of explanation, may also be described as being arranged on the semiconductor layer 110. The first metal layer 121 may be insulated from the semiconductor layer 110. In particular, the gate insulating layer 102 may be arranged between the first metal layer 121 and the semiconductor layer 110, and the first metal layer 121 and the semiconductor layer 110 may be insulated from each other by the gate insulating layer 102.

The first metal layer 121 may include a first metal material, and the first metal material may have a first etch rate under a predetermined condition. For example, the first metal material may include Al. Al may be advantageous for forming a low resistive line.

The first metal layer 121 may have a first side surface making a first acute angle α with respect to an upper surface of the substrate 100. The first side surface of the first metal layer 121 may be described as having the first acute angle with respect to an upper surface of the gate insulating layer 102, which is parallel to the upper surface of the substrate 100, or with respect to an upper surface of the semiconductor layer 110, which is parallel to the upper surface of the substrate 100.

For example, the first acute angle α may be greater than or equal to 40 degrees and less than or equal to 85 degrees and desirably, may be greater than or equal to 50 degrees and less than or equal to 70 degrees. The first acute angle α is a taper angle and has a size that may vary according to a width of an upper surface of the first metal layer 121. As a taper angle of a side surface of the first metal layer 121 increases, the width of the upper surface of the first metal layer 121 may increase. On the contrary, as the taper angle of the side surface of the first metal layer 121 decreases, the width of the upper surface of the first metal layer 121 may decrease.

The second metal layer 122 may be arranged on the first metal layer 121 and may contact the upper surface of the first metal layer 121. That is, a lower surface of the second metal layer 122 and the upper surface of the first metal layer 121 may directly contact each other. The second metal layer 122 may include a second metal material, and the second metal material may have a second etch rate under the predetermined condition for patterning of the first gate layer 120a. The second etch rate may be less than the first etch rate under the same condition. For example, the second metal material may include Ti, which in many situations etches more slowly than does AL.

When viewed in a direction perpendicular to the substrate 100, the second metal layer 122 may be arranged within boundaries of the upper surface of the first metal layer 121. That is, when viewed in the direction perpendicular to the substrate 100, an area of an upper surface of the second metal layer 122 may be less than an area of the upper surface of the first metal layer 121. Alternatively, an edge of the upper surface of the second metal layer 122 may be arranged to coincide with an edge of the upper surface of the first metal layer 121.

A side surface of the second metal layer 122 may have a stair-shaped step difference in the direction perpendicular to the substrate 100 with respect to the upper surface of the first metal layer 121. That is, the side surface of the second metal layer 122 may be stacked, in a thickness direction, on the upper surface of the first metal layer 121, and the side surface of the second metal layer 122, and the upper surface and the side surface of the first metal layer 121 may form a stair shape.

The second metal layer 122 may include a second side surface having a second acute angle β with respect to the upper surface of the substrate 100. The second side surface of the second metal layer 122 may be described as having the second acute angle β with respect to the upper surface of the gate insulating layer 102, which is parallel to the upper surface of the substrate 100, or with respect to the upper surface of the semiconductor layer 110, which is parallel to the upper surface of the substrate 100. Here, the second acute angle β may be less than the first acute angle α described above. For example, the second acute angle β may be greater than or equal to 40 degrees and less than or equal to 85 degrees and desirably, may be greater than or equal to 50 degrees and less than or equal to 70 degrees. A size of the second acute angle β may vary according to a width of the upper surface of the second metal layer 122. As a taper angle of a side surface of the second metal layer 122 increases, the width of the upper surface of the second metal layer 122 may increase.

A difference between the taper angles of the side surface of the first metal layer 121 and the side surface of the second metal layer 122 may be due to a difference in etch rates. As the etch rate of a layer increases, a taper angle of the side surface may increase to be relatively steeper. On the contrary, as the etch rate decreases, the taper angle of the side surface may decrease to be relatively more gradual.

When two or more layers are simultaneously etched, and when an etch rate of a layer arranged below is greater than an etch rate of a layer arranged above, the lower layer may have an undercut structure after being etched. Thus, because the first metal layer 121 may be arranged below the second metal layer 122 and an etch rate of the first metal layer 121 may be greater than an etch rate of the second metal layer 122, the first metal layer 121 may have an undercut structure. That is, the first metal layer 121 may be formed to have an undercut structure by an etch process.

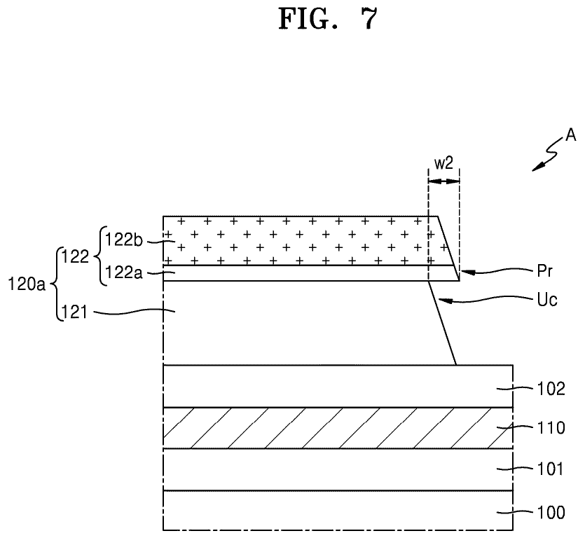

If the first metal layer 121 has an undercut structure, the second metal layer 122 may have a protrusion portion (hereinafter, see protrusion portion Pr of FIG. 7) protruding in a direction parallel to the substrate 100. The protrusion portion Pr may be unintentionally electrically connected to other metal layers, such as a second gate layer, etc., covering the second metal layer 122 or may cause a short phenomenon.

However, the second metal layer 122 may serve as a capping layer. The second metal layer 122 may be needed as the capping layer to prevent damage to the first metal layer 121, which may occur in a process of forming at least one contact hole.

A height h1 of the first metal layer 121 may be greater than or equal to 1500 Å and less than or equal to 6000 Å and desirably, may be about 2400 Å. The height h1 of the first metal layer 121 may vary according to a size of the display apparatus or a drive frequency of the display apparatus.

The second metal layer 122 may include a first sub-layer 122a contacting the upper surface of the first metal layer 121 and including nitride of the second metal material and a second sub-layer 122b contacting an upper surface of the first sub-layer 122a and including the second metal material. For example, the nitride of the second metal material may include TiN, and the second metal material may include Ti. For example, when viewed in a direction perpendicular to the substrate 100, the second sub-layer 122b may be arranged within the boundaries of the upper surface of the first sub-layer 122a. That is, when viewed in the direction perpendicular to the substrate 100, an area of an upper surface of the second sub-layer 122b may be less than an area of the upper surface of the first sub-layer 122a. Also, a side surface of the second sub-layer 122b and a side surface of the first sub-layer 122a may form a continuous surface.

In an embodiment, a height h2-1 of the first sub-layer 122a may be greater than or equal to 150 Å and less than or equal to 900 Å and desirably, may be about 400 Å. A height h2-2 of the second sub-layer 122b may be greater than or equal to 150 Å and less than or equal to 1500 Å and desirably, may be about 500 Å. A height h2 of the second metal layer 122 may be greater than or equal to 300 Å and less than or equal to 2400 Å and desirably, may be about 900 Å.

When viewed in the direction perpendicular to the substrate 100, an edge of a contact surface at which a lower surface of the first sub-layer 122a and the upper surface of the first metal layer 121 contact each other may be spaced apart from an edge of the upper surface of the first metal layer 121. Here, the edge of the contact surface at which the lower surface of the first sub-layer 122a and the upper surface of the first metal layer 121 contact each other may be spaced apart from the edge of the upper surface of the first metal layer 121 by a first width W1. For example, the first width W1 may be greater than or equal to 0 Å and less than or equal to 800 Å and desirably, may be greater than or equal to 50 Å and less than or equal to 400 Å.

The height h1 of the first metal layer 121 may be greater than the height h2 of the second metal layer 122. The height h1 of the first metal layer 121 may be greater than a height h2-1 of the first sub-layer 122a. The height h1 of the first metal layer 121 may be greater than a height h2-2 of the second sub-layer 122b. The term “height” in this description may denote the height measured in the direction perpendicular to the substrate 100 with respect to the same reference surface or may denote a thickness of each layer.

The height h1 of the first metal layer 121 may be greater than the height h2 of the second metal layer 122 so that relatively more of the first metal material (for example, Al) is used in the first gate layer 120a, which may allow a pattern to be more easily formed. As a result, patterning of the first gate layer 120a may become relatively easier.

The height h2-1 of the first sub-layer 122a may be less than the height h2-2 of the second sub-layer 122b. The first sub-layer 122a may be used to increase adhesion between the first metal layer 121 and the second sub-layer 122b, and thus, the height h2-1 of the first sub-layer 122a may be relatively less.

Hereinafter, the method of manufacturing the display apparatus (hereinafter, the manufacturing method) according to an embodiment is described in detail below.

For reference, when describing the manufacturing method, aspects that are repeated or the same as the aspects with respect to the display apparatus according to an embodiment described above may be omitted.

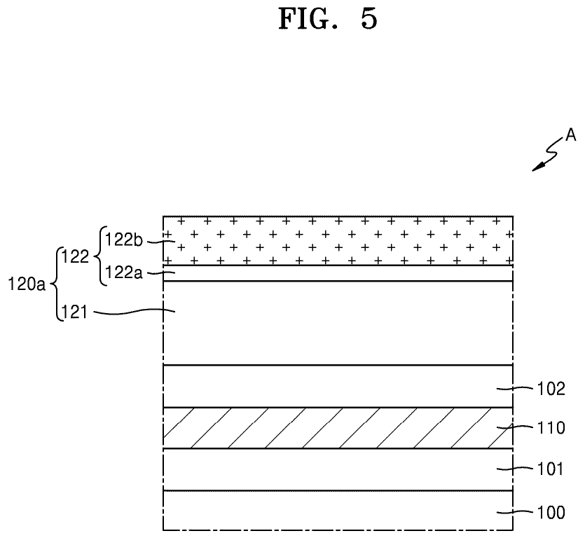

FIGS. 5 to 9 are schematic cross-sectional views of the region A of FIG. 3 for sequentially describing the manufacturing method for the display apparatus.

As illustrated in FIG. 5, the manufacturing method according to the disclosure may include forming the semiconductor layer 110 on the substrate 100. The forming of the semiconductor layer 110 may include preparing the substrate 100, forming the buffer layer 101 on the substrate 100, and forming the semiconductor layer 110 on the buffer layer 101.

Preparing of the substrate 100 may include preparing areas of the substrate corresponding to the display area DA and the peripheral area PA outside the display area DA. According to a display apparatus to be manufactured, the substrate 100 may include polymer resins and may be flexible, bendable, etc.

The forming of the buffer layer 101 on the substrate 100 may include forming a barrier layer (not shown) on the substrate 100 and then forming the buffer layer 101 on the formed barrier layer. Here, the barrier layer may include an inorganic material and may form a layered structure together with the substrate 100.

The forming of the semiconductor layer 110 may include depositing or growing the semiconductor layer 110 on the buffer layer 101 and patterning the semiconductor layer 110 to have a predetermined shape. For convenience of explanation, it may be described that the semiconductor layer 110 may be formed on the substrate 100. The semiconductor layer 110 may be patterned to have a predetermined shape by a photolithography process and an etch process.

As illustrated in FIG. 5, the manufacturing method according to the disclosure may further include, after the forming of the semiconductor layer 110, forming, on the semiconductor layer 110, the first metal layer 121 including a first metal material having a first etch rate under a predetermined condition.

The forming of the first metal layer 121 may include forming the gate insulating layer 102 on the semiconductor layer 110 after the semiconductor layer 110 is formed or patterned and forming the first metal layer 121 on the gate insulating layer 102 after the gate insulating layer 102 is formed.

The forming of the gate insulating layer 102 on the semiconductor layer 110 may correspond to a process of applying chemical vapor deposition (CVD) or plasma enhanced CVD (PECVD). The gate insulating layer 102 may include an inorganic material, such as silicon oxide, silicon nitride, and/or silicon oxynitride, and may be arranged between the semiconductor layer 110 and the first metal layer 121.

The forming of the first metal layer 121 on the gate insulating layer 102 may include forming the first metal layer 121 through deposition, such as CVD, thermal CVD (TCVD), PECVD, etc., which uses a metal material, after the gate insulating layer 102 is formed. Here, the first metal layer 121 may include the first metal material described above, and the first metal material may have a first etch rate under a predetermined condition. For example, the first metal material may include Al.

As a result of being etched by the first etch rate, a resulting side surface of the first metal layer 121 may extend at a first acute angle α relative to an upper surface of the gate insulating layer 102, which is parallel to an upper surface of the substrate 100, or relative to an upper surface of the semiconductor layer 110, which is parallel to the upper surface of the substrate 100.

For example, the first acute angle α may be greater than or equal to 40 degrees and less than or equal to 85 degrees and desirably, may be greater than or equal to 50 degrees and less than or equal to 70 degrees. A size of the first acute angle α may vary according to a width of an upper surface of the first metal layer 121. As a taper angle of a side surface of the first metal layer 121 increases, the width of the upper surface of the first metal layer 121 may increase. On the contrary, as the taper angle of the side surface of the first metal layer 121 decreases, the width of the upper surface of the first metal layer 121 may decrease.

As illustrated in FIG. 5, the manufacturing method according to the disclosure may further include, after the forming of the first metal layer 121, forming, on the first metal layer 121, the second metal layer 122 including a second metal material having a second etch rate under a predetermined condition.

As a result of being etched by the second etch rate, a resulting side surface of the second metal layer 122 may extend at a second acute angle β relative to the upper surface of the gate insulating layer 102, which is parallel to the upper surface of the substrate 100, or relative to the upper surface of the semiconductor layer 110, which is parallel to the upper surface of the substrate 100. Here, the second acute angle β may be less than the first acute angle α described above.

For example, the second acute angle β may be greater than or equal to 40 degrees and less than or equal to 85 degrees and desirably, may be greater than or equal to 50 degrees and less than or equal to 70 degrees. A size of the second acute angle β may vary according to a width of the upper surface of the second metal layer 122. As a taper angle of a side surface of the second metal layer 122 increases, the width of the upper surface of the second metal layer 122 may increase.

The forming of the second metal layer 122 may include forming the second metal layer 122 through deposition, such as CVD, TCVD, PECVD, etc., which uses a metal material. Here, the second metal layer 122 may include the second metal material described above, and the second metal material may have a second etch rate under a predetermined condition. For example, the second metal material may include Ti.

The forming of the second metal layer 122 may include forming, on the first metal layer 121, the first sub-layer 122a including nitride of the second metal material and forming, on the second sub-layer 122b, the second sub-layer 122b including the second metal material. For example, the nitride of the second metal material may include TIN, and the second metal material may include Ti.

The forming of the first sub-layer 122a may include forming the first sub-layer 122a through deposition, such as CVD, TCVD, PECVD, etc. Here, the first sub-layer 122a may include the nitride of the second metal material described above, and the nitride of the second metal material may include a compound of the second metal material having the second etch rate under a predetermined condition. For example, the nitride of the second metal material may include TiN.

The forming of the second sub-layer 122b may include forming the second sub-layer 122b through deposition, such as CVD, TCVD, PECVD, etc., which uses a metal material. Here, the second sub-layer 122b may include the second metal material described above, and the second metal material may have the second etch rate under the predetermined condition. For example, the second metal material may include Ti.

As a result after an etching process, when viewed in a direction perpendicular to the substrate 100, the second sub-layer 122b may be arranged within the boundaries of an upper surface of the first sub-layer 122a. That is, when viewed in the direction perpendicular to the substrate 100, an area of an upper surface of the second sub-layer 122b may be less than an area of the upper surface of the first sub-layer 122a. Also, a side surface of the second sub-layer 122b and a side surface of the first sub-layer 122a may form a continuous surface.

For example, a height of the first sub-layer 122a may be greater than or equal to 150 Å and less than or equal to 900 Å and desirably, may be about 400 Å. A height of the second sub-layer 122b may be greater than or equal to 150 Å and less than or equal to 1500 Å and desirably, may be about 500 Å. A height of the second metal layer 122 may be greater than or equal to 300 Å and less than or equal to 2400 Å and desirably, may be about 900 Å.

After etching, when viewed in the direction perpendicular to the substrate 100, an edge of a contact surface at which a lower surface of the first sub-layer 122a and the upper surface of the first metal layer 121 contact each other may be spaced apart from an edge of the upper surface of the first metal layer 121. Here, the edge of the contact surface at which the lower surface of the first sub-layer 122a and the upper surface of the first metal layer 121 contact each other may be spaced apart from the edge of the upper surface of the first metal layer 121 by a first width W1. For example, the first width W1 may be greater than or equal to 0 Å and less than or equal to 800 Å and desirably, may be greater than or equal to 50 Å and less than or equal to 400 Å.

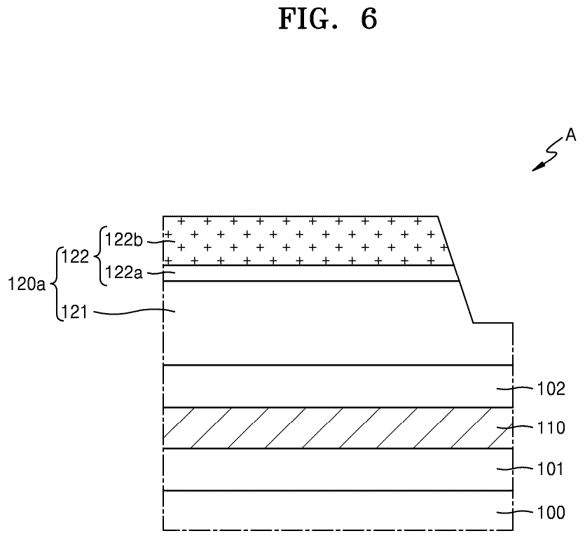

As illustrated in FIG. 6, the manufacturing method according to the disclosure may further include, after the forming of the second metal layer 122, etching the second metal layer 122. When the second metal layer 122 is etched, a portion of the first metal layer 121 may also be etched.

The etching of the second metal layer 122 may correspond to patterning the second metal layer 122 to have a predetermined shape. The formed second metal layer 122 may be patterned to have a predetermined shape by a photolithography process and an etch process using a mask. Here, the photolithography process may use a negative photoresist or a positive photoresist.

The mask may be divided into a transmission area transmitting light and a blocking area blocking transmission of light. However, in certain cases, a halftone mask, etc. may be used, and the type of the mask may be variously changed, and embodiments disclosed herein are not limited to specific types of masks.

The etching of the second metal layer 122 may correspond to etching a portion of the first metal layer 121 while etching the second metal layer 122. That is, an over etching process, in which etching is excessively performed, may be applied in a process of patterning the second metal layer 122, and thus, a portion of the first metal layer 121 may be etched together with the second metal layer 122. Thus, the etched portion of the first metal layer 121 may be etched to correspond to the predetermined shape into which the second metal layer 122 is patterned.

The etching of the second metal layer 122 may include etching the second metal layer 122 by using a first etching gas including Cl₂ gas and BCl₃ gas.

For example, a flow rate of the Cl₂ gas in the first etching gas may be 2000 standard cubic centimeter per minute (sccm), and a flow rate of the BCl₃ gas may be greater than or equal to 200 sccm and less than or equal to 4000 sccm. Desirably, when the flow rate of the Cl₂ gas of the first etching gas is 2000 sccm, the flow rate of the BCl₃ gas may be greater than or equal to 500 sccm and less than or equal to 2000 sccm. As a detailed example, when the flow rate of the Cl₂ gas included in the first etching gas is about 2000 sccm, the flow rate of the BCl₃ gas may be about 500 sccm.

In other words, a ratio between the flow rate of the Cl₂ gas and the flow rate of the BCl₃ gas included in the first etching gas may be within a range of 10:1 to 1:2 and desirably, may be within a range of 4:1 to 1:1. As a detailed example, the ratio between the flow rate of the Cl₂ gas and the flow rate of the BCl₃ gas included in the first etching gas may be about 4:1 (in units of sccm).

These numerical ranges may be summarized by [Table 1] below.

TABLE 1

| Gas | Unit | Numerical Range | Desirable Numerical Range |
|---|---|---|---|
| Cl₂/BCl₃ | sccm | 2000/200 to 2000/4000 | 2000/500 to 2000/2000 |
| | | (10:1 to 1:2) | (4:1 to 1:1) |

An etching process using the first etching gas having the composition ratio of the composition as shown in [Table 1] above may be appropriate for the etching process of the second metal layer 122. The first metal layer 121 including the first metal material, such as Al, which is relatively easily etched, may be etched together, and thus, it is important to use an etching gas for preventing the etching of the first metal layer 121 as much as possible. The first etching gas having the composition ratio of the composition as shown in [Table 1] above may be appropriate for etching the second metal layer 122 and may minimize etching of the first metal layer 121.

As illustrated in FIG. 7, the manufacturing method according to the disclosure may further include forming an undercut structure Uc on the side surface of the first metal layer 121.

The forming of the undercut structure Uc may correspond to additionally etching the first metal layer 121 after etching the second metal layer 122. The forming of the undercut structure Uc may correspond to minimizing etching of the second metal layer 122 and mainly etching the first metal layer 121. The forming of the undercut structure Uc may result from a difference in etch rate between the first metal layer 121 and the second metal layer 122. That is, when an etch rate of the first metal layer 121 is higher than an etch rate of the second metal layer 122, the first metal layer 121 may be etched more than the second metal layer 122, and thus, the undercut structure Uc may be formed. Due to the undercut structure Uc, the second metal layer 122 may include the protrusion portion Pr protruding by a second width W2 in a direction parallel to the substrate 100.

The forming of the undercut structure Uc may include etching the first metal layer 121 by using a second etching gas including Cl₂ gas, BCl₃ gas, and N₂ gas. The same mask used when etching with the first etching gas may be used when etching with the second etching gas. The flow rates of the BCl₃ gas and the N₂ gas included in the second etching gas may be changed.

For example, when a flow rate of the Cl₂ gas and a flow rate of the N₂ gas of the second etching gas are constant, a flow rate of the BCl₃ gas may be changed. When the flow rate of the Cl₂ gas is about 600 sccm, and the flow rate of the N₂ gas is about 90 sccm, the flow rate of the BCl₃ gas may be greater than or equal to 200 sccm and less than or equal to 3000 sccm. Desirably, when the flow rate of the Cl₂ gas is about 600 sccm, and the flow rate of the N₂ gas is about 90 sccm, the flow rate of the BCl₃ gas may be greater than or equal to 500 sccm and less than or equal to 2400 sccm. As a detailed example, the flow rate of the Cl₂ gas may be about 600 sccm, the flow rate of the BCl₃ gas may be about 1800 sccm, and the flow rate of the N₂ gas may be about 90 sccm, the Cl₂ gas, the BCl₃ gas, and the N₂ gas being simultaneously included in the second etching gas.

In other words, the flow rate of the Cl₂ gas, the flow rate of the BCl₃ gas, and the flow rate of the N₂ gas, included in the second etching gas, may have relative proportions within a range of 1:0.33:0.15 to 1:5:0.15 and desirably, may be within a range of 1:0.5:0.15 to 1:4:0.15. As a detailed example, the relative proportions of the flow rate of the Cl₂ gas, the flow rate of the BCl₃ gas, and the flow rate of the N₂ gas, included in the second etching gas, may be about 1:3:0.15 (in units of sccm).

For example, when the flow rates of the Cl₂ gas and the BCl₃ gas are constant, the flow rate of the N₂ gas may be changed. When the flow rate of the Cl₂ gas is about 600 sccm, and the flow rate of the BCl₃ gas is about 1800 sccm, the flow rate of the N₂ gas may be greater than or equal to 30 sccm and less than or equal to 1800 sccm. Desirably, when the flow rate of the Cl₂ gas is about 600 sccm, and the flow rate of the BCl₃ gas is about 1800 sccm, the flow rate of the N₂ gas may be greater than or equal to 90 sccm and less than or equal to 1200 sccm. As a detailed example, the flow rate of the Cl₂ gas may be about 600 sccm, the flow rate of the BCl₃ gas may be about 1800 sccm, and the flow rate of the N₂ gas may be 90 sccm, the Cl₂ gas, the BCl₃ gas, and the N₂ gas being included in the second etching gas.

In other words, the flow rate of the Cl₂ gas, the flow rate of the BCl₃ gas, and the flow rate of the N₂ gas, included in the second etching gas, may have relative proportions within a range of 1:3:0.05 to 1:3:3 and desirably, may be within a range of 1:3:0.15 to 1:3:2. As a detailed example, the flow rate of the Cl₂ gas, the flow rate of the BCl₃ gas, and the flow rate of the N₂ gas, included in the second etching gas, may have relative proportions of about 1:3:0.15 (in units of sccm). These numerical ranges may be summarized by [Table 2] below.

TABLE 2

| | | | Desirable |
|---|---|---|---|
| Gas | Unit | Numerical Range | Numerical Range |
| Cl₂/BCl_{3/N2} | sccm | 1) Change of the Flow | 1) Change of the Flow |
| | | Rate of BCl₃ | Rate of BCl₃ |
| | | 600/200/90 to | 600/500/90 to |
| | | 600/3000/90 | 600/2400/90 |
| | | (1:0.33:0.15 to 1:5:0.15) | (1:0.5:0.15 to 1:4:0.15) |
| | | 2) Change of the Flow | 2) Change of the Flow |
| | | Rate of N₂ | Rate of N₂ |
| | | 600/1800/30 to | 600/1800/90 to |
| | | 600/1800/1800 | 600/1800/1200 |
| | | (1:3:0.05 to 1:3:3) | (1:3:0.15 to 1:3:2) |

An etching process using the second etching gas having a composition as shown in [Table 2] above may be appropriate for etching of the first metal layer 121 and may minimize etching of the second metal layer 122. Also, by adjusting the flow rate of the BCl₃ gas and/or the flow rate of the N₂ gas, the relative etch rates of the first metal layer 121 and the second metal layer 122 may be easily adjusted.

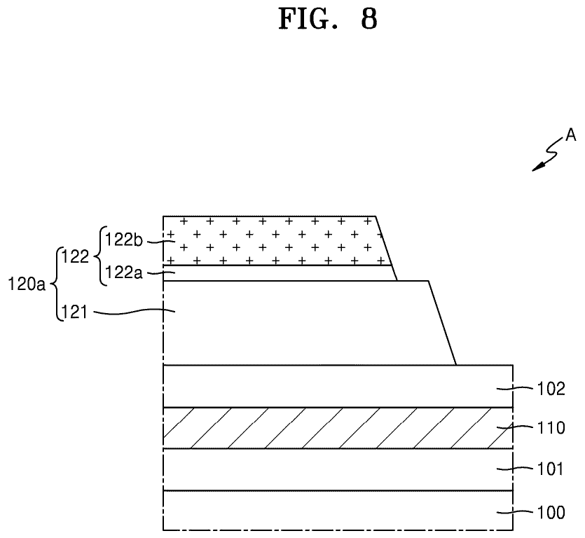

As illustrated in FIG. 8, the manufacturing method according to the disclosure may include etching the protrusion portion Pr of the second metal layer 122, generated due to the undercut structure Uc.

The etching of the protrusion portion Pr of the second metal layer 122 may correspond to an additional process of patterning the second metal layer 122 to have a predetermined shape. The formed second metal layer 122 may be patterned to have a predetermined shape by a photolithography process and an etch process using a mask. Here, the photolithography process may use a negative photoresist or a positive photoresist.

The etching of the protrusion Pr of the second metal layer 122 may use the same mask that was used when etching with the first etching gas and the second etching gas. The etching of the protrusion portion Pr of the second metal layer 122 may include etching the protrusion portion Pr by using a third etching gas including CF₄ gas and Ar gas.

For example, when a flow rate of the Ar gas of the third etching gas is about 1000 sccm, a flow rate of the CF₄ gas may be greater than or equal to 200 sccm and less than or equal to 1000 sccm. Desirably, when the flow rate of the Ar gas is about 1000 sccm, the flow rate of the CF₄ gas may be greater than or equal to 400 sccm and less than or equal to 600 sccm. As a detailed example, when the flow rate of the Ar gas is about 1000 sccm, the flow rate of the CF₄ gas may be about 600 sccm.

In other words, a ratio between the flow rate of the CF₄ gas and the flow rate of the Ar gas included in the third etching gas may be within a range of 1:5 to 1:1 and desirably, may be within a range of 2:5 to 3:5. As a detailed example, the ratio between the flow rate of the CF₄ gas and the flow rate of the Ar gas included in the third etching gas may be about 3:5 (in units of sccm).

These numerical ranges may be summarized by [Table 3] below.

TABLE 3

| Gas | Unit | Numerical Range | Desirable Numerical Range |
|---|---|---|---|
| CF₄/Ar | sccm | 200/1000 to 1000/1000 | 400/1000 to 600/1000 |
| | | (1:5 to 1:1) | (2:5 to 3:5) |

An etching process using the third etching gas having the composition ratio of the composition as shown in [Table 3] above may be appropriate for the etching process of the protrusion portion Pr of the second metal layer 122. The first metal layer 121 including the first metal material, such as Al, which is relatively easily etched, may be etched together, and thus, it is important to use an etching gas for preventing the etching of the first metal layer 121 as much as possible. In addition, because only a portion of the second metal layer 122 has to be etched, it is necessary to appropriately mix in the Ar gas, which has no reactivity. As described above, the third etching gas having the composition ratio as shown in [Table 3] above may be appropriate for etching the protrusion portion Pr of the second metal layer 122 and may minimize etching of the remaining portion of the second metal layer 122 and the first metal layer 121.

With respect to the protrusion portion Pr of the second metal layer 122, a lower surface of the second metal layer 122 may protrude from an upper surface of the first metal layer 121 in a direction parallel to the substrate 100. The etching of the protrusion portion Pr of the second metal layer 122 may include etching the protrusion portion Pr of the second metal layer 122 such that a side surface of the second metal layer 122 may have a stair-shaped step difference with respect to the upper surface of the first metal layer 121.

The etching of the protrusion portion Pr of the second metal layer 122 may include etching the protrusion portion Pr of the second metal layer 122 such that an edge of a contact surface at which the lower surface of the second metal layer 122 and the upper surface of the first metal layer 121 contact each other is spaced apart from an edge of the upper surface of the first metal layer 121.

As described above, the manufacturing method according to the disclosure may include a total of three etching processes, and by these etching processes, the first metal layer 121 and the second metal layer 122 may be patterned. According to the manufacturing method according to an embodiment of the disclosure, the protrusion portion Pr of the second metal layer 122, which may be generated during the patterning process of the first metal layer 121 and the second metal layer 122, may be removed, and thus, a short problem between the first gate layer and the second gate layer, which may occur due to the protrusion portion Pr, may be prevented.

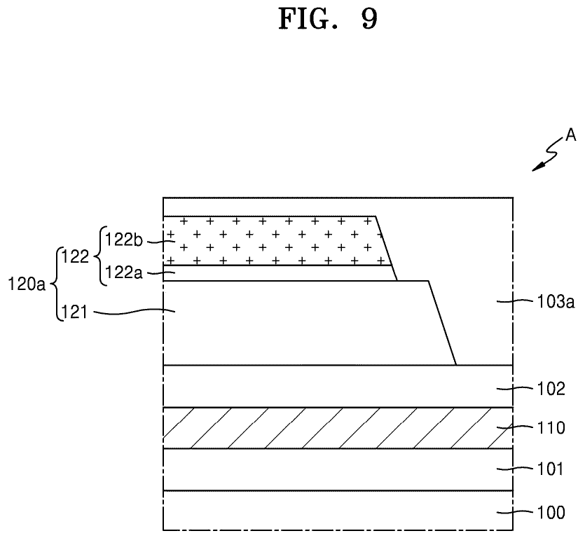

As illustrated in FIG. 9, the manufacturing method according to the disclosure may include forming a first interlayer insulating layer on the second metal layer 122.

The forming of the first interlayer insulating layer may include forming the first interlayer insulating layer by using CVD or PECVD.

The first interlayer insulating layer may cover an upper surface of the gate insulating layer 102, which is upwardly exposed by the etching process, may cover a side surface of the first metal layer 121, and may cover a portion of the upper surface of the first metal layer 121, the portion being upwardly exposed by the etching process. Also, the first interlayer insulating layer may cover the second metal layer 122.

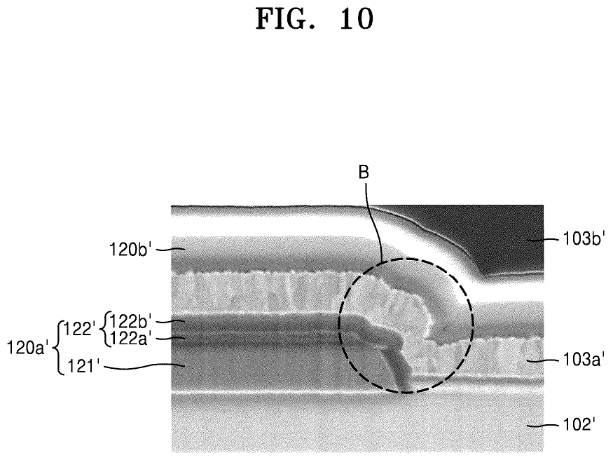

FIG. 10 is a cross-sectional view schematically illustrating a display apparatus by focusing on a 1^{st}′ metal layer 121′ and a 2^{nd}′ metal layer 122′ of the display apparatus according to a comparative embodiment.

For reference, the 1^{st}′ metal layer 121′ according to the comparative embodiment may correspond to the first metal layer 121 of the disclosure, and the 2^{nd}′ metal layer 122′ may correspond to the second metal layer 122 of the disclosure. In addition, elements described according to the comparative embodiment may correspond to the elements according to the disclosure.

With respect to a region B of FIG. 10, the display apparatus according to the comparative embodiment may include an undercut structure resulting from a difference in etch rate between the 1^{st}′ metal layer 121′ and the 2^{nd}′ metal layer 122′ during pattering of a first gate layer. The 2^{nd}′ metal layer 122′ of the display apparatus according to the comparative embodiment may have a protrusion portion, and due to the protrusion portion, damage may occur to a first interlayer insulating layer 103a′, or an insulating state between the 2^{nd}′ metal layer 122′ and a second gate layer may be damaged. Thus, it is important to remove the protrusion portion of the 2^{nd}′ metal layer 122′.

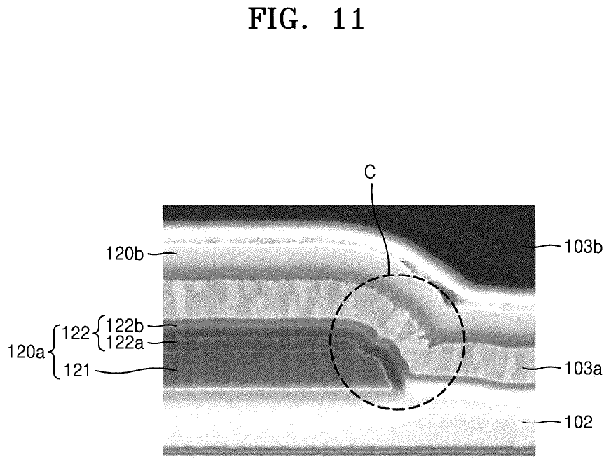

FIG. 11 is a cross-sectional view schematically illustrating a display apparatus by focusing on a first metal layer and a second metal layer of the display apparatus according to an embodiment. For reference, the display apparatus illustrated in FIG. 11 may be manufactured by the manufacturing method according to an embodiment of the disclosure.

With respect to a region C of FIG. 11, the protrusion portion of the second metal layer 122 is absent. Composition ratios of a first etching gas to a third etching gas for manufacturing the display apparatus of FIG. 11 are shown in [Table 4] below.

TABLE 4

| | Gas | Ratio of | |
|---|---|---|---|
| | Composition | Flow Rates | Range of Flow rates |
| First | Cl₂/BCl₃ | 4:1 to 1:1 | 2000/500 to |
| Etching Gas | | | 2000/2000 |
| Second | Cl₂/BCl₃/N₂ | 1:0.5:0.15 to | 600/500/90 to |
| Etching Gas | | 1:4:0.15 | 600/2400/90 |
| | | or | or |
| | | 1:3:0.15 to 1:3:2 | 600/1800/90 to |
| | | | 600/1800/1200 |
| Third | CF₄/Ar | 2:5 to 3:5 | 400/1000 to 600/1000 |
| Etching Gas | | | |

[Table 5] below shows data for comparison of a display apparatus containing the structure of FIG. 10 and a display apparatus containing the structure of FIG. 11.

TABLE 5

| | Display Apparatus | Display Apparatus |
|---|---|---|
| | of FIG. 11 | of FIG. 10 |
| Breakdown Voltage (V) | 59 | 48 |
| Pixel-Off (%) | 4.96 | 24.22 |

As shown in [Table 5], the display apparatus of FIG. 11 is significantly different from the display apparatus of FIG. 10 according to the comparative embodiment, in terms of the breakdown voltage and the pixel-off. As the pixel-off decreases, the pixel yield rate from the manufacturing process increases.

As described above, according to one or more of the above embodiments, a display apparatus or a manufacturing method may avoid electrical shorting caused by protrusion structures that result from a difference in etch rates. However, the scope of the disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a semiconductor layer arranged on the substrate;
a first metal layer arranged on the semiconductor layer, insulated from the semiconductor layer, and including a first metal material having a first etch rate under a predetermined condition; and
a second metal layer on the first metal layer, contacting an upper surface of the first metal layer, and arranged within boundaries of the upper surface of the first metal layer when viewed in a direction perpendicular to the substrate, the second metal layer including a second metal material having a second etch rate under the predetermined condition, the second etch rate being less than the first etch rate.

2. The display apparatus of claim 1, wherein the first metal material includes aluminum (AI), and the second metal material includes titanium (Ti).

3. The display apparatus of claim 1, wherein the second metal layer includes:
a first sub-layer contacting the upper surface of the first metal layer and including a nitride of the second metal material; and
a second sub-layer contacting an upper surface of the sub-layer and including the second metal material.

4. The display apparatus of claim 3, wherein, when viewed in the direction perpendicular to the substrate, the second sub-layer is arranged within boundaries of the upper surface of the sub-layer.

5. The display apparatus of claim 3, wherein, when viewed in the direction perpendicular to the substrate, an edge of a contact surface at which a lower surface of the first sub-layer and the upper surface of the first metal layer contact each other is spaced apart from an edge of the upper surface of the first metal layer.

6. The display apparatus of claim 3, wherein a side surface of the second metal layer has a stair-shaped step difference with respect to the upper surface of the first metal layer.

7. The display apparatus of claim 1, wherein
the first metal layer includes a first side surface extending at a first acute angle relative to an upper surface of the substrate, and
the second metal layer includes a second side surface extending at a second acute angle relative to the upper surface of the substrate, the second acute angle being less than the first acute angle.

8. A method of manufacturing a display apparatus, the method comprising:
forming a semiconductor layer on a substrate;
forming, on the semiconductor layer, a first metal layer including a first metal material having a first etch rate under a predetermined condition;
forming, on the first metal layer, a second metal layer including a second metal material having a second etch rate under the predetermined condition;
etching the second metal layer and a portion of the first metal layer;
forming an undercut structure at a side surface of the first metal layer, the undercut structure including a protrusion portion of the second metal layer that extends beyond the side surface of the first metal layer; and
etching the protrusion portion of the second metal layer.

9. The method of claim 8, wherein the forming of the second metal layer includes:
forming, on the first metal layer, a first sub-layer including a nitride of the second metal material; and
forming, on the first sub-layer, a second sub-layer including the second metal material.

10. The method of claim 8, wherein the first metal material includes aluminum (Al), and the second metal material includes titanium (Ti).

11. The method of claim 8, wherein the etching of the second metal layer and the portion of the first metal layer includes etching the second metal layer and the portion of the first metal layer by using a first etching gas including chlorine (Cl₂) gas and boron trichloride (BCl₃) gas.

12. The method of claim 11, wherein in the first etching gas, a ratio between a flow rate of the Cl₂ gas and a flow rate of the BCl₃ gas is in a range from 10:1 to 1:2.

13. The method of claim 8, wherein the forming of the undercut structure at the side surface of the first metal layer includes etching the first metal layer by using a second etching gas including Cl₂ gas, BCl₃ gas, and nitrogen gas (N₂ gas).

14. The method of claim 13, wherein in the second etching gas, a flow rate of the Cl₂ gas, a flow rate of the BCl₃ gas, and a flow rate of the N₂ gas have relative proportions in a range of 1:0.33:0.15 to 1:5:0.15 or 1:3:0.05 to 1:3:3.

15. The method of claim 8, wherein the etching of the protrusion portion of the second metal layer includes etching the protrusion portion of the second metal layer by using a third etching gas including tetrafluoromethane (CF₄) gas and argon (Ar) gas.

16. The method of claim 15, wherein in the third etching gas, a ratio between a flow rate of the CF₄ gas and a flow rate of the Ar gas is in a range from 1:5 to 1:1.

17. The method of claim 8, wherein the protrusion portion includes a lower surface of the second metal layer, the lower surface protruding from an upper surface of the first metal layer in a direction parallel to the substrate.

18. The method of claim 8, wherein
the first metal layer includes a first side surface extending at a first acute angle relative to an upper surface of the substrate, and
the second metal layer includes a second side surface extending at a second acute angle relative to the upper surface of the substrate, the second acute angle being less than the first acute angle.

19. The method of claim 8, wherein the etching of the protrusion portion of the second metal layer includes etching the protrusion portion of the second metal layer such that a side surface of the second metal layer has a stair-shaped step difference with respect to an upper surface of the first metal layer.

20. The method of claim 8, wherein the etching of the protrusion portion of the second metal layer includes etching the protrusion portion of the second metal layer such that, when viewed in a direction perpendicular to the substrate, an edge of a contact surface at which a lower surface of the second metal layer and an upper surface of the first metal layer contact each other is spaced apart from an edge of the upper surface of the first metal layer.
